(19) United States
(12) Patent Application Publication
(10) Pub. No.: US 2026/0201601 A1
(43) Pub. Date: Jul. 16, 2026

(54) NEGATIVE ACTIVE MATERIAL, LITHIUM SECONDARY BATTERY CONTAINING THE SAME, AND METHOD FOR MANUFACTURING THE NEGATIVE ACTIVE MATERIAL

(71) Applicant: EBS SQUARE, Inc., Seongnam-si (KR)

(72) Inventors: Sung Won HWANG, Hwaseong-si (KR); Min Kyoung NA, Seoul (KR); Hyun Hee JUNG, Seoul (KR)

(73) Assignee: EBS SQUARE, Inc., Seongnam-si (KR)

(21) Appl. No.: 19/368,081

(22) Filed: Oct. 24, 2025

(30) Foreign Application Priority Data
Jan. 15, 2025 (KR) 10-2025-0006305
Sep. 24, 2025 (KR) 10-2025-0137710

(51) Int. Cl. C30B 9/04; C30B 29/06; C30B 33/02; H01M 10/052

(52) U.S. Cl. CPC C30B 9/04; C30B 29/06; C30B 33/02; H01M 10/052

(57) ABSTRACT

A negative active material according to an embodiment may include a composite including a silicon-based active material and a nanoribbon surrounding the silicon-based active material.

### CROSS-REFERENCE TO RELATED APPLICATION(S)

This application claims benefit of priority to Korean Patent Application No. 10-2025-0006305 filed on Jan. 15, 2025 and No. 10-2025-0137710 filed on Sep. 24, 2025 in the Korean Intellectual Property Office, the disclosure of which is incorporated herein by reference in its entirety.

### BACKGROUND

### 1. Field

The present disclosure relates to a negative active material including a silicon-based active material and having improved electric capacity, electrochemical properties, structural stability, and electrical conductivity, a lithium secondary battery containing the same, and a method for manufacturing the negative active material.

### 2. Description of Related Art

Recently, due to the rapid growth of electric vehicle, energy storage system (ESS), and mobile device markets, a demand for lithium secondary batteries with high energy density, high output, and long lifespan characteristics has increased. Conventional lithium secondary batteries have already achieved a certain level or more of performance in terms of energy density, lifespan, and stability, but an energy density of 1,000 Wh/L or more is required in high-performance applications such as electric vehicles. Accordingly, an increase in the capacity of a negative active material, which is a core component of the lithium secondary batteries, has emerged as an important technical challenge.

Graphite, which is a commercially available negative electrode material for lithium secondary batteries, has a stable structure and long lifespan characteristics, but has a theoretical capacity of only about 374 mAh/g, and thus, has limitations in in realizing a high-energy-density cell. For this reason, research into a high-capacity negative electrode material such as silicon (Si) and silicon oxide (SiOₓ) has been actively conducted. Silicon has a very high theoretical capacity of 3,579 mAh/g, and SiOₓ exhibits a lower expansion rate and more excellent cycle characteristics than silicon. Accordingly, silicon and SiOₓ have attracted attention as next-generation negative electrode material candidates.

However, a silicon-based negative electrode material undergoes volume expansion of 300% or more during charge and discharge, resulting in structural and electrochemical instability such as particle fragmentation, electrode separation, and repeated formation of a solid electrolyte interphase (SEI) layer. In particular, SiOX forms irreversible by-products such as Li₂O and LiₓSiO_{y} during a lithiation process, thereby causing a decrease in initial efficiency and lithium loss. This instability leads to a rapid capacity reduction and a cycle life reduction. In addition, due to low electrical conductivity, it is difficult to achieve high-speed charge and discharge characteristics, and it is essential to make a conductive material composite in order to secure an electron transport path.

In order to solve these problems, a design of a composite structure capable of controlling the volume expansion of a silicon-based active material, improving electrical conductivity, and ensuring structural stability has emerged as an important technical challenge. In particular, graphene-based carbon materials are known to be effective in suppressing the expansion of silicon-based particles and stabilizing the SEI, owing to their excellent conductivity and mechanical strength.

### SUMMARY

An aspect of the present disclosure provides a silicon-based active material composite including a silicon-based active material having excellent electrochemical performance and structural stability and a nanoribbon forming a network of the silicon-based active material.

A negative active material according to an embodiment includes a composite including a silicon-based active material and a nanoribbon surrounding the silicon-based active material.

The composite includes a core including the silicon-based active material and a shell surrounding the core and including the nanoribbon.

The shell has a thickness of 5 nm to 50 nm.

The composite has a porous structure.

The composite has an average particle diameter of 50 nm to 5 μm.

The silicon-based active material includes at least one of Si and SiOₓ (0<x≤2).

The silicon-based active material has a single-crystal structure.

The composite has characteristic peaks observed on (111), (220), and (311) crystal planes during XRD pattern analysis.

The nanoribbon includes graphene.

The nanoribbon has a thickness of 5 to 50 nm.

A lithium secondary battery according to another embodiment includes a negative electrode including the negative active material; a positive electrode including a positive active material; and an electrolyte transferring lithium ions to the positive electrode and the negative electrode.

The lithium secondary battery exhibits a capacity retention of 97% or more after 500 or more charge and discharge cycles at a current density of 0.2 A/g.

The lithium secondary battery exhibits a capacity of 1500 mAh/g or more at a current density of 0.1 A/g.

A method for manufacturing a negative active material according to another embodiment includes a pretreating step of manufacturing and purifying a silicon-based active material; and a composite manufacturing step of manufacturing a composite of a core-shell structure using the pretreated silicon-based active material and a graphene nanoribbon precursor.

The pretreating step includes: melting a silicon-based precursor; and condensing the molted silicon-based particles, and the composite manufacturing step includes: forming a carbon nanoribbon shell outside the annealed particles.

### BRIEF DESCRIPTION OF THE DRAWINGS

FIG. 1 is a schematic cross-sectional view of a composite including a silicon-based active material and a carbon nanoribbon according to an embodiment of the present disclosure.

FIG. 2 is a schematic view of the surface of a negative active material including a plurality of composites according to an embodiment of the present disclosure.

FIG. 3 is a field emission scanning electron microscope (FE-SEM) image showing a negative active material including the composite manufactured according to an embodiment of the present disclosure.

FIG. 4 is an FE-SEM image showing a negative active material including the composite manufactured according to an embodiment of the present disclosure.

FIG. 5 is a high-resolution transmission electron microscope (HR-TEM) image showing a negative active material including the composite e manufactured according to an embodiment of the present disclosure.

FIGS. 6a and 6b are graphs showing the results of X-ray photoelectron spectroscopy (XPS) for analyzing a surface chemical composition of the composite according to an embodiment of the present disclosure.

FIG. 7 shows the results of an X-ray diffraction (XRD) pattern for analyzing a crystal structure of the composite according to an embodiment of the present disclosure.

FIG. 8 is a graph showing the results of Raman spectroscopy analysis of the composite according to an embodiment of the present disclosure.

FIGS. 9a and 9b are graphs showing the initial charge and discharge voltage-capacity curves and the cyclic voltammetry (CV) curves of a composite-based battery according to an embodiment of the present disclosure.

FIGS. 10a and 10b are graphs showing rate capability, long-cycle characteristics, and coulombic efficiency of a GNR/Si composite-based battery according to an embodiment of the present disclosure.

### DETAILED DESCRIPTION

Throughout the present specification, like reference numerals refer to like components. It should be noted that the present specification does not describe all elements of the embodiments, and general contents in the art to which the present disclosure pertains, or repetitive descriptions among the embodiments, are omitted.

Throughout the present specification, when a certain portion is “connected” to another portion, it should be understood that this includes not only a direct connection but also an indirect connection, such as a connection via a wireless communication network.

Furthermore, when a certain portion “includes” a specific component, it should be understood that this does not exclude the presence of other components, and the portion may further include other components, unless explicitly stated otherwise.

A singular expression includes the corresponding plural forms, unless the context clearly indicates otherwise.

In addition, the terms such as “~unit,” “~er/or,” “~block,” “~member,” and “~module” may refer to a unit that processes at least one function or operation. For example, the above terms may refer to at least one hardware such as a field-programmable gate array (FPGA) or an application-specific integrated circuit (ASIC), at least one software stored in a memory, or at least one process executed by a processor.

Reference numerals assigned to respective steps are used for identifying the steps, and do not indicate the order of the steps. Unless the context clearly specifies a particular order, the steps may be carried out in an order different from that described.

Hereinafter, embodiments of a solid electrolyte according to an aspect and a secondary battery containing the same will be described in detail with reference to the accompanying drawings. The embodiments described herein and the configurations illustrated in the drawings are merely exemplary of the most preferred embodiment of the present disclosure, and various equivalents or modifications may be substituted for them at the time of filling this application.

### <Negative Active Material>

A negative active material is a compound capable of reversibly intercalating and deintercalating lithium ions.

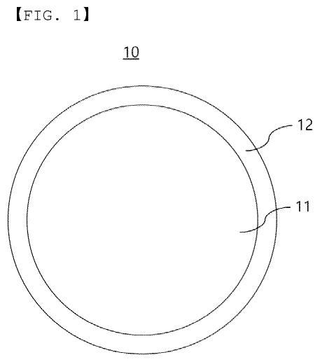

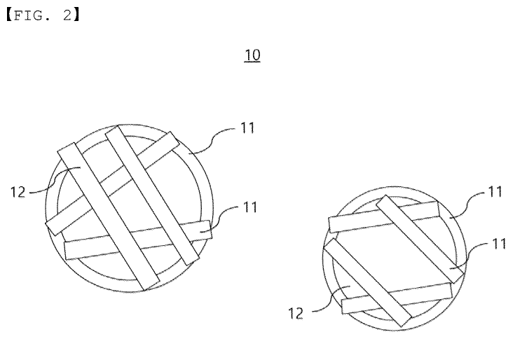

FIG. 1 is a schematic cross-sectional view of a composite including a silicon-based active material and a carbon nanoribbon according to an embodiment of the present disclosure, and FIG. 2 is a schematic view of the surface of a negative active material including a plurality of composites.

Referring to FIGS. 1 and 2, the negative active material includes a composite 10 including a silicon-based active material and a nanoribbon surrounding the silicon-based active material.

The composite 10 may have a core-shell structure. Specifically, the composite 10 may include a core 11 including a silicon-based active material and a shell 12 surrounding the core 11 and including the nanoribbon.

The core 11 is positioned at the center of the composite and may include a silicon-based active material, and the silicon-based active material may include at least one of Si and SiOₓ (0<x≤2), enabling reversible intercalation and deintercalation of lithium ions. The core 11 may be provided as porous silicon particles, thereby serving to secure diffusion paths for lithium ions and to buffer volume expansion occurring during charge and discharge. The core 11 may have a particle size of 50 nm to 5 μm or less.

The shell 12 may be formed on an outer surface of the core 11 to surround the core 11 and may include a nanoribbon. The shell 12 may be provided to surround all or a portion of the surface of the core 11. The shell 12 absorbs mechanical stress caused by volume expansion of the core 11 and provides an electrical conduction path, thereby serving to enhance the structural stability and electrochemical properties of the composite 10. The shell 12 may have a thickness of 5 nm to 50 nm or less, and preferably 10 nm or less, and thus may be configured to uniformly surround the core 11.

The nanoribbon, which is a carbon-based one-dimensional structure formed in a ribbon shape along the longitudinal direction, has an average thickness on the nanometer (nm) scale, and may have a structure that maintains single-crystal crystallinity. Specifically, the nanoribbon may have a ribbon-shaped nanostructure with a width of about 1 nm to 999 nm and a length of about 1 nm to 999 nm. Preferably, the nanoribbon may be graphene nanoribbon (GNR) or a carbon nanoribbon. The nanoribbon may additionally secure structural flexibility of the ribbon shape while maintaining excellent electrical conductivity and mechanical strength. Therefore, when the nanoribbon forms the composite 10 together with a silicon-based active material, the nanoribbon may contribute to the enhancement of electrochemical and mechanical properties. The nanoribbon may include a material such as Cu or Al, in addition to graphene.

This composite 10 has a core-shell structure, and thus has advantages such as improved electrical conductivity, controlled volume expansion of the silicon-based active material, SEI stabilization, and improved structural stability through a uniform shell structure.

A silicon-based active material may be included in the composite 10 in a weight ratio of 50 to 90 relative to the total weight of the composite, and a nanoribbon may be included in the composite 10 in a weight ratio of 10 to 50 relative to the total weight of the composite.

TABLE 1

| Silicon-based | Nanoribbon | Key characteristics and |
|---|---|---|
| material (wt %) | (wt %) | use purpose |
| 90 | 10 | Aimed at high capacity, expansion |
| | | suppression effect is low |
| 80 | 20 | Practical high capacity (>2,500 |
| | | mAh/g), supplementation of |
| | | mechanical stability |
| 70 | 30 | Securing of balance between cycle |
| | | life and stability, aimed at |
| | | commercialization |
| 60 | 40 | High stability, advantageous for |
| | | fast charge and discharge |
| | | conditions |
| 50 | 50 | Low-expansion and high-stability |
| | | design, applied to |
| | | all-solid-state batteries and |
| | | systems requiring high stability |

As shown in Table 1, by adjusting the weight ratio of the silicon-based active material and the weight ratio of the nanoribbons, a balance between stability and capacity may be adjusted. Specifically, when the weight ratio of the silicon-based active material is higher than that of the nanoribbons, for example, when the weight ratio of the silicon-based active material is 90 wt % and the weight ratio of the nanoribbon is 10 wt %, high capacity may be achieved, but the expansion suppression effect is limited. On the other hand, when the weight ratio of the silicon-based active material is lower than that of the nanoribbons, for example, when the weight ratio of the silicon-based active material is 50 wt % and the weight ratio of the nanoribbon is 50 wt %, a low-expansion and high-stability design is possible.

### <Negative Electrode>

The negative electrode includes a current collector, and a negative electrode material layer formed on the current collector and including a negative active material, a conductive agent, a binder, etc. For example, the negative electrode of the present disclosure may be obtained by preparing a coating slurry by mixing a negative active material, a binder, a conductive agent, a thickener, and a solvent such as an organic solvent or water, applying the coating slurry onto the current collector, drying the solvent or water, and then press-molding to form a negative electrode material layer. The current collector may be made of, for example, copper.

The negative active material may be the negative active material described above, and may be included in an amount of 50 wt % to 95 wt %, preferably 85 wt %, based on 100 parts by weight of the negative electrode material layer.

The conductive agent may include a carbon-based material having excellent electrical conductivity, preferably carbon black. The conductive agent may be included in an amount of 1 wt % to 15 wt %, preferably 10 wt %, based on 100 parts by weight of the negative electrode material layer.

The binder is not particularly limited and may include, for example, styrene-butadiene copolymers; (meth)acrylic copolymers obtained by copolymerizing ethylenically unsaturated carboxylic acid esters, such as methyl (meth)acrylate, ethyl (meth)acrylate, butyl (meth)acrylate, (meth)acrylonitrile, and hydroxyethyl (meth)acrylate, with ethylenically unsaturated carboxylic acids, such as acrylic acid, methacrylic acid, itaconic acid, fumaric acid, and maleic acid; and polymer compounds such as polyvinylidene fluoride, polyethylene oxide, polyepichlorohydrin, polyphosphazene, polyacrylonitrile, polyimide, and polyamideimide.

The binder may be included in an amount of 0.1 wt % to 20 wt %, preferably 5 wt % in the negative electrode material layer. When the binder content is 0.1 wt % or more, favorable adhesion is obtained, and the destruction of the negative electrode caused by expansion and contraction during charge and discharge tends to be suppressed. Meanwhile, when the binder content is 20 wt % or less, an increase in electrode resistance tends to be suppressed.

### <Lithium Secondary Battery>

A lithium secondary battery according to the present disclosure includes a positive electrode, the negative electrode, and an electrolyte.

The lithium-ion secondary battery may be formed, for example, by arranging a positive electrode to face a negative electrode through a separator, and then injecting an electrolyte solution containing an electrolyte.

The positive electrode may be obtained in the same manner as the negative electrode, by forming a positive electrode material layer on the surface of the current collector. The positive electrode current collector may be made of, for example, aluminum.

The positive active material of the positive electrode material layer of the lithium secondary battery according to the present disclosure is a compound capable of reversibly intercalating and deintercalating lithium ions. Specifically, the positive active material may include a lithium metal oxide containing lithium and one or more metals, such as cobalt, manganese, nickel, or aluminum. Examples of the lithium metal oxide include lithium-manganese-based oxide lithium-cobalt-based oxide, lithium-nickel-based oxide, lithium-cobalt-nickel-based oxide, lithium-nickel-manganese-cobalt-based oxide, or lithium iron phosphate.

The electrolyte is not particularly limited and any known electrolyte may be used. For example, a non-aqueous lithium-ion secondary battery may be manufactured by using a solution in which an electrolyte is dissolved in an organic solvent as a liquid electrolyte. Examples of electrolytes include LiPF₆, LiClO₄, LiBF₄, LiClF₄, LiAsF₆, LiSbF₆, LiAlO₄, LiAlCl₄, LiN(CF₃SO₂)₂, LiN(C₂F₅SO₂)₂, LiC(CF₃SO₂)₃, LiCl, and LiI. As the organic solvent, any solvent capable of dissolving the electrolyte may be used. Examples thereof include propylene carbonate, ethylene carbonate, diethyl carbonate, ethyl methyl carbonate, vinyl carbonate, Y-butyrolactone, 1,2-dimethoxyethane, and 2-methyltetrahydrofuran.

On the other hand, the electrolyte is not limited to liquid electrolytes and may also be a solid electrolyte.

As a separator, a variety of known separators may be used. Specific examples include paper separators, polypropylene separators, polyethylene separators, and glass fiber separators.

However, when a solid electrolyte is used, the separator may not be included in the lithium secondary battery.

### Example 1

### Manufacture of Negative Active Material

In this example, a composite-type negative active material including a silicon-based active material and a graphene nanoribbon (GNR) was manufactured.

A silicon precursor was pretreated using ball milling to control particle size and dispersion characteristics. The pretreated silicon precursor was introduced into in an induction melting and heating device and subjected to evaporation, cooling, and condensation processes to synthesize micrometer-sized porous silicon particles.

Subsequently, a copper thin film was deposited on the surface of the silicon particles, and then a carbon precursor (e.g., acetylene, methane, etc.) was pyrolyzed to grow a graphene nanoribbon (GNR), thereby forming single-crystal GNR on the surface of the silicon particles. Then, surface defects were removed under a mixed atmosphere of O₂ and Ar gases.

The formed GNR/Si composite was annealed at 680° C. for 3 hours under a nitrogen atmosphere, then dispersed in an ethanol solvent and stirred at room temperature for 6 hours. A pH was then adjusted to 9 with an aqueous ammonia solution, stirred for 4 hours, and sonicated for 2 hours.

The stirred slurry was dried in an oven at 90° C. and then calcined for 4 hours under an argon atmosphere at 450° C. with a heating rate of 5° C./min, thereby finally obtaining a GNR/Si composite-type negative active material.

### Manufacture of Electrode (Half-Cell)

A negative electrode was manufactured based on the negative active material including the manufactured composite. The negative electrode slurry was formulated to have a composition of the negative active material, a binder (CMC and SBR), and a conductive agent (Super P), and the weight ratio of negative active material:binder:conductive agent was adjusted to 85:5:10.

The slurry was uniformly mixed using a Thinky mixer (2, 500 rpm, 2 minutes), coated on a copper current collector, and then dried in a vacuum oven at 120° C. for 8 hours to manufacture an electrode. The dried electrode was subjected to a rolling process using a roll press to improve electrode density.

Subsequently, the manufactured negative electrode and lithium metal were combined to assemble a half-cell within a glovebox. A general separator and electrolyte solution were used in the cell assembly, and the electrochemical properties were evaluated using a WBCS-3000 battery cycler (Won A Tech).

### <Physical Property Evaluation>

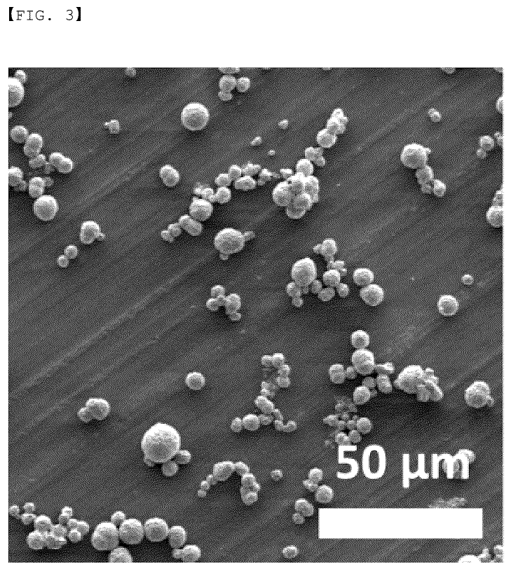

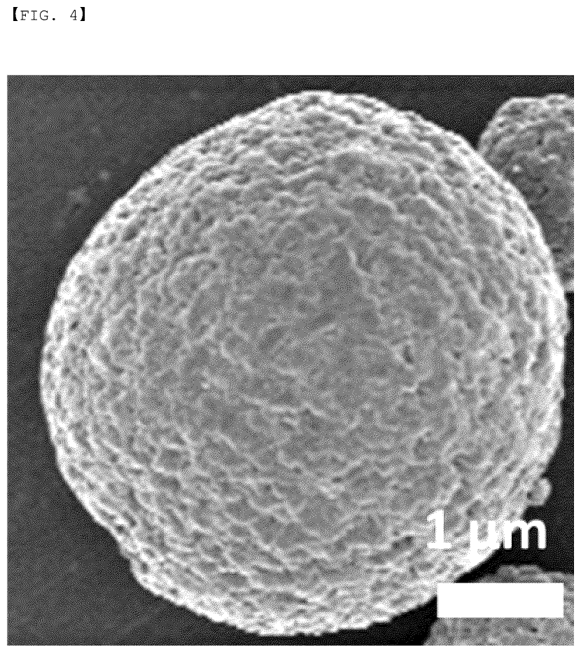

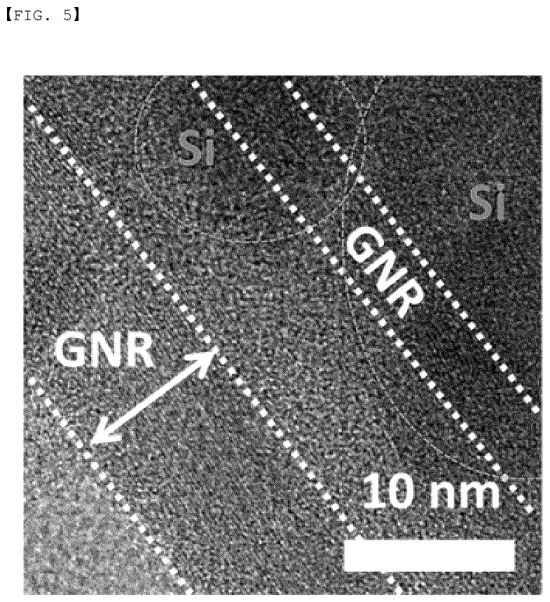

FIGS. 3 and 4 are FE-SEM images showing a negative active material including the composite manufactured according to Example 1 of the present disclosure, and FIG. 5 is an HR-TEM image showing a negative active material including the composite manufactured according to an embodiment of the present disclosure.

Referring to FIGS. 3 to 5, the composite includes a core including silicon microparticles with a size of about 4 μm, and has a spherical composite structure with a graphene nanoribbon (GNR) uniformly formed on the surface of the particles.

The composite according to the present disclosure was synthesized by controlling the pyrolysis reaction of a carbon gas precursor (e.g., acetylene, methane, etc.), and during the pyrolysis reaction, single-crystal graphene nanoribbons were grown on the surface of the silicon particles to form the composite. The GNR, having an average thickness of less than nm, were formed as a shell structure surrounding the core, and a uniform graphene layer maintaining a single-crystal structure was confirmed when observed from the outside.

The composite according to the present disclosure has a structure in which the porous structure of silicon microparticles is combined with a thin and continuous outer shell structure of the GNR, and it is considered that such a composite is formed by in-out diffusion reactions among the components occurring during the pyrolysis process.

In addition, according to the TEM analysis results, no defect structure was observed within the silicon particles, indicating that the silicon particles were manufactured based on a single-crystal structure. In contrast, the carbon-based GNR layer forming the outer shell of the composite was observed to exhibit a highly crystalline single-crystal structure.

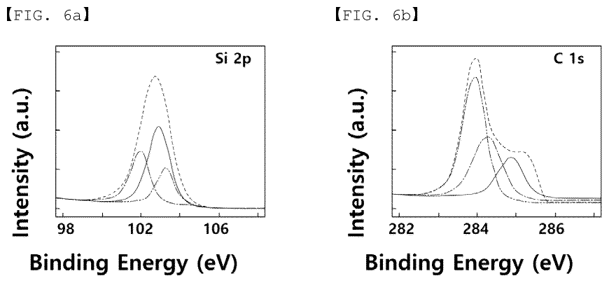

FIGS. 6a and 6b are graphs showing the results of X-ray photoelectron spectroscopy (XPS) for analyzing a surface chemical composition of the composite according to Example 1 of the present disclosure. FIG. 6a is an XPS graph showing the Si 2p binding energy of the composite according to Example 1 of the present disclosure, and FIG. 6b is an XPS graph showing the C 1s binding energy of the composite according to Example 1 of the present disclosure.

Referring to FIGS. 6a and 6b, as a result of the full-range XPS scan of the composite, characteristic peaks corresponding to Si 2p, Si 2s, C 1s, and O 1s were confirmed at 103.0 eV, 156.0 eV, 287.0 eV, and 532.0 eV, respectively. Through this, it was confirmed that the composite included only Si, C, and O, without other impurity elements, which is consistent with the results of the previous XRD analysis.

Referring to FIG. 6a, as a result of the Si 2p core-level scan analysis in the range of 96 to 110 eV, broad peaks were observed at 101.9 eV, 103.1 eV, and 103.8 eV, which correspond to Si²⁺, Si³⁺, and Si⁴⁺, respectively. This is interpreted as the result of the formation of various Si species depending on the surface oxidation state of the silicon particles during the manufacturing process, and indicates that silicon in a stable oxidation state predominates. In contrast, no peaks corresponding to Si⁰ or Si⁺ were observed, which suggests that the instability of Si particles was suppressed during the composite manufacturing process.

In contrast, in the case of a general Si/C simple synthesis, a thick SiOₓ layer may be formed, and the carbon shell may be non-uniformly coated, leading to weakening or disappearance of the Si⁰ signal of the core.

Referring to FIG. 6b, in the C 1s core-level scan performed in the binding energy range of 280 to 288 eV, peaks corresponding to Si—C bonds (284.0 eV), C—C bonds (284.2 eV), and C—OH bonding (284.9 eV) were detected, respectively. General carbon nanotube (CNT)-based structures are primarily formed through C—C bonds, but in the GNR/Si nanocomposite according to the present disclosure, it was confirmed that a single-crystal carbon shell formed through a direct growth pyrolysis process on a copper substrate exists primarily in the form of Si—C bonds.

In contrast, in the simple Si/C composite, the proportion of C—OH bonds tends to increase relatively due to —OH group adsorption during a hydrothermal synthesis process, which is a characteristic distinguishing it from the GNR composite.

As a result, the GNR/Si nanocomposite according to the present disclosure provides abundant active sites for lithium ions, while the outer GNR shell with low defects provides a stable Li⁺ storage structure and an excellent electronic conduction path, thereby enabling rapid reaction kinetics and superior electrochemical performance.

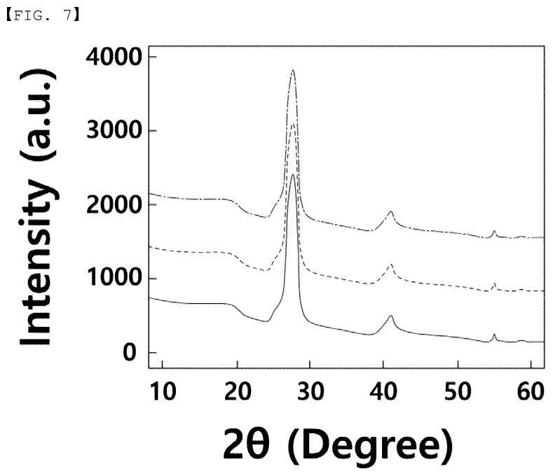

FIG. 7 shows the results of an X-ray diffraction (XRD) pattern for analyzing a crystal structure of the composite according to Example 1 of the present disclosure. In an embodiment of the present disclosure, X-ray diffraction (XRD) analysis was performed to analyze the crystal structures of the manufactured composite and raw material. The measurements were performed in the 20 range of 20 to 80° with a step size of 0.02° and a step time of 2 s, under an acceleration voltage of 40 kV and a current of 100 mA. The crystallinity of the composite raw material and the coating layer of the composite were confirmed through XRD analysis results.

Referring to FIG. 7, in the composite according to Example 1 of the present disclosure, distinct diffraction peaks were observed at 2θ=28.7°, 41.4°, and 56.1°, which were analyzed as the characteristic peaks corresponding to the (111), (220), and (311) crystal planes of crystalline silicon, respectively.

The above results indicate that the silicon particles were included in the composite structure while maintaining crystallinity, suggesting that the crystal structure of the silicon was not damaged by thermal or chemical treatments during the manufacturing process.

Meanwhile, for comparison, the carbon nanotubes (CNTs) analyzed exhibited diffraction peaks at 20=25.8° and 43.7°, respectively, which are peaks correspond to the (002) and (101) crystal planes of a graphite structure, reflecting the characteristic structure of CNTs.

In the GNR/Si nanocomposite according to the present disclosure, the silicon crystal peaks and diffraction characteristics according to the carbon-based structure of the graphene nanoribbon (GNR) were confirmed simultaneously. Through this, it may demonstrate that the two components were composited in a structurally conformal state and the crystallinity of the components was maintained during the entire synthesis process.

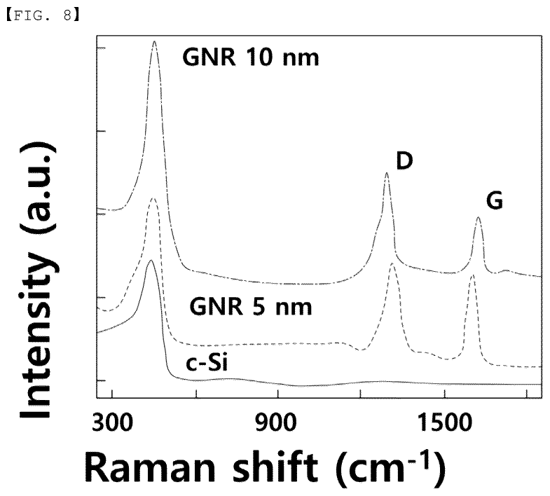

FIG. 8 shows the results of Raman spectroscopy analysis to confirm the structural characteristics of the composite according to Example 1 of the present disclosure.

Referring to FIG. 8, this analysis was performed at room temperature for each of a 10 nm GNR/Si composite and a 5 nm GNR/Si composite, and the Raman spectral characteristics of the two samples were compared and analyzed.

In general, in the Raman spectra of carbon-based materials, the D band observed at about 1, 356 cm⁻¹ corresponds to a disordered or defective amorphous carbon structure, and the G band observed at about 1, 582 cm⁻¹ corresponds to a highly crystalline graphitized carbon structure.

In the case of the GNR/Si nanocomposite, the I_D/I_G ratio was found to be about 1.25, which indicates that a predetermined proportion of amorphous carbon exists in the composite. It is analyzed that this is primarily due to mesoporous carbon formed during the pyrolysis process on the copper substrate.

On the other hand, the single-crystal graphene nanoribbon (GNR) structure included in the composite was evaluated as contributing to the enhancement of Li⁺ diffusion rate and improvement of interfacial permeability.

In addition, a characteristic Raman peak of silicon was confirmed at about 523 cm⁻¹, and in the GNR/Si nanocomposite according to the present disclosure, a blue shift of this peak to 524 cm⁻¹ was observed. This peak shift is interpreted as a masking effect caused by the amorphous silicon structure and the GNR layer coated on the surface of the silicon particle, which structurally demonstrates that the GNR shell effectively surrounds the Si core.

As a result, the Raman peak position and intensity of the GNR/Si composite show a pattern that changes depending on the thickness and structure of the GNRs, which is considered to reflect the crystallinity, amorphousness, and interaction with silicon of the carbon structures in the composite.

### <Electrochemical Analysis>

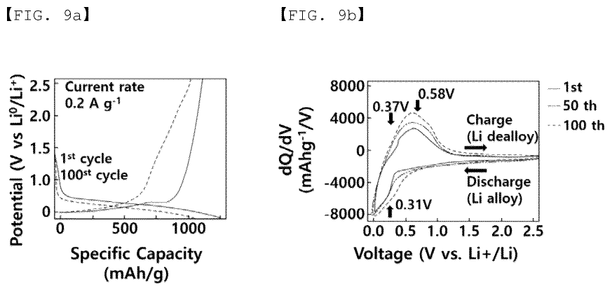

FIGS. 9a and 9b show the initial charge and discharge voltage-capacity profile measured at a current density of 0.2 A/g to confirm the initial charge and discharge characteristics of the GNR/Si nanocomposite structure according to Example 1 of the present disclosure, and the results of cyclic voltammetry (CV) analysis performed on a unit cell using the GNR/Si nanocomposite, respectively.

Referring to FIG. 9a, the initial charge and discharge capacities were measured to be 1,114 mAh/g and 1,257 respectively, with initial coulombic efficiency mAh/g, confirmed to be about 88.6%.

The decrease in initial coulombic efficiency is interpreted as a result of the consumption of a significant amount of Li⁺ ions due to the formation of a solid electrolyte interphase (SEI) thin film and irreversible reactions with silicon oxides and other materials during the initial charge and discharge cycles.

The GNR/Si nanocomposite-based negative electrode exhibited stable expression of high capacity, which is attributed to the enhanced specific surface area and structural stability of the electrode resulting from the high-density structure of the GNR/Si composite and the mesoporous carbon-based matrix structure. In addition, additional capacity increase was induced by an alloying reaction between Si and Li during the charge and discharge process.

In particular, the silicon microparticles and the GNR shell structure severs to effectively buffer the volume expansion of Si during charge and discharge, while maintaining the stability of the nano-micro composite structure, thereby enabling excellent electrochemical cycle performance.

The GNR suppressed non-uniform aggregation of Si particles while providing a rapid electron transport path to reduce internal resistance of the electrode, and the porous structure of the composite also provided a diffusion path for lithium ions, thereby ensuring high-rate charge and discharge performance.

Referring to FIG. 9b, the test was performed in the voltage range of 0.01 to 3 V, and during the discharge process of the first cycle, two reduction peaks were observed at 0.31 V and 0.38 V. This indicates that an SEI film was successfully formed through the large surface area of the GNR/Si composite.

In addition, during the oxidation process, an oxidation peak was observed at 0.58 V, and as the cycle was repeated, the intensity of the peak gradually decreased, which is interpreted as a result of the modification of the electrode surface and the improvement in its electrochemical stability.

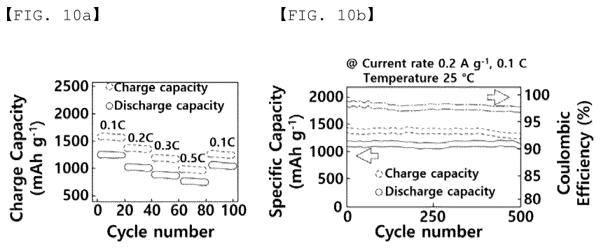

FIGS. 10a and 10b show the results of evaluating the rate capability of a lithium secondary battery including the GNR/Si nanocomposite according to Example 1 of the present disclosure as a negative active material, and the results of evaluating the long cycle performance and coulombic efficiency of a battery using the GNR/Si nanocomposite, respectively.

Referring to FIG. 10a, a battery using the negative active material according to the present disclosure exhibited excellent cycle characteristics, showing a capacity retention of 98.5% or more for 100 cycles or more under various charge and discharge rate conditions of 0.1, 0.2, 0.5, and 1 C-rates.

In addition, it was confirmed that even under high-rate charge and discharge conditions of 0.5, 1, and 2 C-rates, the battery maintained a relatively higher capacity compared with a battery using a conventional silicon/graphite composite negative electrode. In particular, a high cycle stability of 97% or more was shown under the condition of 0.1 C.

These characteristics are analyzed as resulting from the conformal formation of the graphene nanoribbon (GNR) structure on the surface of the silicon microparticles, which leads to the formation of a stable and uniform solid electrolyte interphase (SEI) layer and a reduced heterogeneous interfacial resistance, thereby facilitating electron and ion transport within the electrode. As a result, the GNR/Si composite was able to realize both high capacity and long-cycle life even under high-rate charge and discharge conditions.

Referring to FIG. 10b, under the condition of a current density of 0.2 A/g, the GNR/Si nanocomposite-based battery exhibited a capacity retention of about 978 even after 500 cycles, with a reversible capacity of 1,114 mAh/g, maintaining high reversible capacity characteristics.

Furthermore, even under the condition of a higher current density of 5 A/g, a reversible capacity of greater than 1110 mAh/g was maintained after 500 cycles, and the coulombic efficiency was also stably maintained at about 97% after 500 cycles.

These results indicate that the GNR/Si nanocomposite possesses structurally excellent stability, and the high electrical conductivity and the porous matrix structure provided by the GNR significantly contributed to the long lifespan characteristics of the battery by maintaining smooth diffusion and electron transfer paths of Lit.

### Example 2

Example 2 is identical to Example 1 in all respects except for the manufacture of the negative active material.

### Manufacture of Negative Active Material

Silicon nano- or microparticles were prepared, and copper or nickel was deposited on the silicon particles to a thickness of 20 nm or less. Thereafter, a shadow mask and a dry etching process, such as inductively coupled plasma reactive ion etching (ICP-RIE) were performed to fabricate metallic micro-ribbons of copper or nickel. Subsequently, by applying the ICP-RIE process, carbon underwent repeated in-diffusion and out-diffusion into a metal structure while being restructured, whereby nanoribbons were directly grown on the silicon particles.

In Example 2, by utilizing a dry etching process used in semiconductor manufacturing called ICP-RIE, the etching speed is increased by increasing the density of ions with high plasma density, and the energy of ions is controlled with a separate RF power source to enable precise anisotropic etching while reducing damage. In other words, this process can be utilized in nanoribbons manufacturing by simultaneously achieving high directionality, etching selectivity, and low-damage characteristics.

### Example 3

Example 3 is identical to Example 1 in all respects except for the manufacture of the negative active material.

### Manufacture of Negative Active Material

Silicon oxide (SiOₓ, 0<x≤2) was subjected to repeated flash annealing using pulse energy at 1,000° C. or more for 10 seconds or less to remove oxygen. Thereafter, copper or nickel was deposited to a thickness of 10 nm or less on the surface of the silicon, followed by performing a shadow mask and a dry etching process, such as inductively coupled plasma reactive ion etching (ICP-RIE) to fabricate metallic micro-ribbons of copper or nickel. Subsequently, by applying the ICP-RIE process, carbon underwent repeated in-diffusion and out-diffusion into a metal structure while being restructured, whereby nanoribbons were directly grown on the silicon particles.

The negative active material according to an embodiment of the present disclosure exhibits excellent electrochemical performance and structural stability by including a silicon-based active material composite including a silicon-based active material and a nanoribbon forming a network of the silicon-based active material.

The negative active material according to an embodiment of the present disclosure has high capacity by including a silicon-based active material and has excellent cycle characteristics due to structural stability.

The negative active material according to an embodiment of the present disclosure provides high electrical conductivity by including a silicon-based active material core and a shell formed on a surface of the core and including a nanoribbon.

The negative active material according to an embodiment of the present disclosure allows an SEI to be uniformly formed by a single-crystal GNR shell and secures initial coulombic efficiency by suppressing irreversible lithium loss.

As described above, embodiments disclosed have been described with reference to the attached drawings. A person having ordinary knowledge in the art to which the present disclosure pertains will understand that the present disclosure may be practiced in forms different from the embodiments disclosed herein without changing its technical spirit or essential features. The embodiments disclosed are merely illustrative and should not be construed as limiting.

[Description of Reference Signs]

10: Composite
11: Core
12: Shell

What is claimed is:

1. A negative active material comprising: a composite including a silicon-based active material and a nanoribbon surrounding the silicon-based active material.

2. The negative active material of claim 1, wherein the composite includes a core including the silicon-based active material and a shell surrounding the core and including the nanoribbon.

3. The negative active material of claim 2, wherein the shell has a thickness of 5 nm to 50 nm.

4. The negative active material of claim 2, wherein the composite has a porous structure.

5. The negative active material of claim 4, wherein the composite has an average particle diameter of 50 nm to 5 μm.

6. The negative active material of claim 5, wherein the silicon-based active material includes at least one of Si and SiOₓ (0<x≤2).

7. The negative active material of claim 6, wherein the silicon-based active material has a single-crystal structure.

8. The negative active material of claim 6, wherein the composite has characteristic peaks observed on (111), (220), and (311) crystal planes during XRD pattern analysis.

9. The negative active material of claim 1, wherein the nanoribbon includes graphene.

10. The negative active material of claim 9, wherein the nanoribbon has a thickness of 5 to 50 nm.

11. A lithium secondary battery comprising:
a negative electrode including the negative active material of claim 1;
a positive electrode including a positive active material; and
an electrolyte transferring lithium ions to the positive electrode and the negative electrode.

12. The lithium secondary battery of claim 11, wherein the lithium secondary battery exhibits a capacity retention of 97% or more after 500 or more charge and discharge cycles at a current density of 0.2 A/g.

13. The lithium secondary battery of claim 11, wherein the lithium secondary battery exhibits a capacity of 1,500 mAh/g or more at a current density of 0.1 A/g.

14. A method for manufacturing a negative active material, the method comprising:
a pretreating step of manufacturing and purifying a silicon-based active material; and
a composite manufacturing step of manufacturing a composite of a core-shell structure using the pretreated silicon-based active material and a graphene nanoribbon precursor.

15. The method of claim 14, wherein the pretreating step includes:
melting a silicon-based precursor; and
condensing the molted silicon-based particles, and
wherein the composite manufacturing step includes:
forming a carbon nanoribbon shell outside the annealed particles.
